(19) United States
(12) Patent Application Publication
(10) Pub. No.: US 2023/0180457 A1
(43) Pub. Date: Jun. 8, 2023

(54) METHOD FOR FORMING CAPACITOR AND SEMICONDUCTOR DEVICE

(71) Applicants: CHANGXIN MEMORY TECHNOLOGIES, INC., Hefei City (CN); BEIJING SUPERSTRING ACADEMY OF MEMORY TECHNOLOGY, Beijing (CN)

(72) Inventors: Mengmeng YANG, Hefei City (CN); Xiaoling WANG, Hefei City (CN)

(73) Assignees: CHANGXIN MEMORY TECHNOLOGIES, INC., Hefei City (CN); BEIJING SUPERSTRING ACADEMY OF MEMORY TECHNOLOGY, Beijing (CN)

(21) Appl. No.: 18/162,997

(22) Filed: Feb. 1, 2023

Related U.S. Application Data
(63) Continuation of application No. PCT/CN2021/124016, filed on Oct. 15, 2021.

(30) Foreign Application Priority Data
Jul. 9, 2021 (CN) 202110777919.1

(51) Int. Cl. H10B 12/00

(52) U.S. Cl. CPC H10B 12/31; H10B 12/033

(57) ABSTRACT

A method for forming a capacitor includes: providing a substrate; sequentially forming a first sacrificial layer and a first support layer for covering the substrate; forming first openings penetrating through the first support layer; sequentially forming a second sacrificial layer and a second support layer for covering a remaining portion of the first support layer; forming through holes which sequentially penetrate through the second support layer, the second sacrificial layer, the remaining portion of the first support layer, and the first sacrificial layer; forming first electrode layers, each first electrode layer covering an inner wall of a respective one of the through holes; forming second openings penetrating through a remaining portion of the second support layer; and sequentially forming a dielectric layer and a second electrode layer for covering the first electrode layers, to form the capacitor.

### CROSS-REFERENCE TO RELATED APPLICATIONS

This is a continuation of International Patent Application No. PCT/CN2021/124016 filed on Oct. 15, 2021, which claims priority to Chinese Patent Application No. 202110777919.1 filed on Jul. 9, 2021. The disclosures of the above-referenced applications are hereby incorporated by reference in their entirety.

### BACKGROUND

A Dynamic Random Access Memory (DRAM) is a semiconductor storage device commonly used in a computer, and is composed of many duplicate memory cells. Each memory cell includes a transistor and a capacitor. A gate of the transistor is connected to a word line, a drain of the transistor is connected to a bit line, and a source of the transistor is connected to the capacitor. A voltage signal on the word line can control the transistor to turn on or turn off, such that data information stored in the capacitor can be read through the bit line, or data information can be written into the capacitor to be stored through the bit line.

As the dimension of a DRAM device becomes smaller and smaller, the depth-to-width ratio of a capacitance hole in the capacitor becomes larger and larger, thus, the capacitor is prone to collapse in a manufacturing process. Therefore, how to provide a capacitor structure with a more stable capacitor support layer is an urgent problem to be solved.

### SUMMARY

The embodiments of the disclosure relate to the technical field of semiconductors, and relate, but are not limited, to a method for forming a capacitor and a semiconductor device.

In view of this, the embodiments of the disclosure provide a method for forming a capacitor and a semiconductor device.

In a first aspect, the embodiment of the disclosure provides a method for forming a capacitor, which includes the following operations.

A substrate is provided.

A first sacrificial layer and a first support layer for covering the substrate are sequentially formed.

A plurality of first openings penetrating through the first support layer are formed, in which the plurality of first openings expose the first sacrificial layer.

A second sacrificial layer and a second support layer for covering a first remaining portion of the first support layer are sequentially formed.

A plurality of through holes which sequentially penetrate through the second support layer, the second sacrificial layer, the first remaining portion of the first support layer, and the first sacrificial layer are formed.

A plurality of first electrode layers are formed, each of the plurality of first electrode layers covering an inner wall of a respective one of the plurality of through holes.

After the plurality of first electrode layers are formed, a plurality of second openings penetrating through a first remaining portion of the second support layer are formed, in which the plurality of first openings are located at different positions than the plurality of second openings in a direction parallel to the substrate.

A dielectric layer and a second electrode layer for covering the plurality of first electrode layers are sequentially formed, so as to form the capacitor.

In a second aspect, the embodiment of the disclosure provides a semiconductor device, which includes at least a substrate, and a capacitor.

The capacitor includes: a plurality of first electrode layers arranged perpendicular to the substrate;

a first support layer arranged parallel to the substrate, in which the first support layer is connected to a first portion of each of sidewalls of the plurality of first electrode layers;

a second support layer arranged parallel to the first support layer, in which the second support layer is connected to a second portion of each of sidewalls of the plurality of first electrode layers, and the first support layer is arranged between the second support layer and the substrate; and

a conductive structure, the conductive structure including a first portion, a second portion, a third portion, and a fourth portion, which are sequentially connected to one another in a direction perpendicular to a plane where the substrate is located, in which the first portion penetrates through the second support layer, the second portion is arranged between the second support layer and the first support layer, the third portion penetrates through the first support layer, and the fourth portion is arranged between the first support layer and the substrate.

In the direction perpendicular to the plane where the substrate is located, a projection of the first portion does not overlap a projection of the third portion.

### BRIEF DESCRIPTION OF THE DRAWINGS

In the accompanying drawings (which are not necessarily drawn to scale), similar reference numerals may denote similar components in different diagrams. The similar reference numerals having different letter suffixes may denote different examples of the similar components. The accompanying drawings generally illustrate various embodiments discussed herein by way of example rather than limitation.

FIG. 1A is a first schematic diagram of forming a capacitor in some implementations;

FIG. 1B is a second schematic diagram of forming a capacitor in some implementations;

FIG. 1C is a third schematic diagram of forming a capacitor in some implementations;

FIG. 1D is a fourth schematic diagram of forming a capacitor in some implementations;

FIG. 1E is a fifth schematic diagram of forming a capacitor in some implementations;

FIG. 1F is a sixth schematic diagram of forming a capacitor in some implementations;

FIG. 1G is a seventh schematic diagram of forming a capacitor in some implementations;

FIG. 1H is an eighth schematic diagram of forming a capacitor in some implementations;

FIG. 1I is a ninth schematic diagram of forming a capacitor in some implementations;

FIG. 2 is an optional flowchart of a method for forming a capacitor according to an embodiment of the disclosure;

FIG. 3A is a first partially schematic diagram of a method for forming a capacitor according to an embodiment of the disclosure;

FIG. 3B is a second partially schematic diagram of a method for forming a capacitor according to an embodiment of the disclosure;

FIG. 3C is a third partially schematic diagram of a method for forming a capacitor according to an embodiment of the disclosure;

FIG. 3D is a fourth partially schematic diagram of a method for forming a capacitor according to an embodiment of the disclosure;

FIG. 3E is a fifth partially schematic diagram of a method for forming a capacitor according to an embodiment of the disclosure;

FIG. 3F is a sixth partially schematic diagram of a method for forming a capacitor according to an embodiment of the disclosure;

FIG. 3G is a seventh partially schematic diagram of a method for forming a capacitor according to an embodiment of the disclosure;

FIG. 3H is an eighth partially schematic diagram of a method for forming a capacitor according to an embodiment of the disclosure;

FIG. 3I is a ninth partially schematic diagram of a method for forming a capacitor according to an embodiment of the disclosure;

FIG. 3J is a tenth partially schematic diagram of a method for forming a capacitor according to an embodiment of the disclosure;

FIG. 3K is an eleventh partially schematic diagram of a method for forming a capacitor according to an embodiment of the disclosure;

FIG. 3L is a twelfth partially schematic diagram of a method for forming a capacitor according to an embodiment of the disclosure;

FIG. 4A is a first partially schematic diagram of a method for forming a capacitor according to an embodiment of the disclosure;

FIG. 4B is a second partially schematic diagram of a method for forming a capacitor according to an embodiment of the disclosure;

FIG. 5A is a first partially schematic diagram of a capacitor with contacts according to an embodiment of the disclosure;

FIG. 5B is a second partially schematic diagram of a capacitor with contacts according to an embodiment of the disclosure;

FIG. 5C is a third partially schematic diagram of a capacitor with contacts according to an embodiment of the disclosure;

FIG. 6A is a first partially schematic diagram of forming an etching stop layer according to an embodiment of the disclosure;

FIG. 6B is a second partially schematic diagram of forming an etching stop layer according to an embodiment of the disclosure;

FIG. 7 is a partially schematic diagram of a semiconductor device according to an embodiment of the disclosure; and

FIG. 8 is a partially schematic diagram of a semiconductor device according to an embodiment of the disclosure.

### DETAILED DESCRIPTION

Specific technical solutions of the disclosure will be further described in detail with reference to the accompanying drawings in the embodiments of the disclosure. The following embodiments are used to describe the disclosure rather than limiting the scope of the embodiment of the disclosure.

In the following descriptions, suffixes for representing elements such as “module” or “unit” are used only for the ease of describing the disclosure, and they have no specific meanings. Therefore, “module” or “unit” may be used interchangeably.

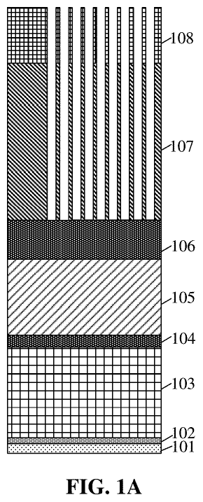

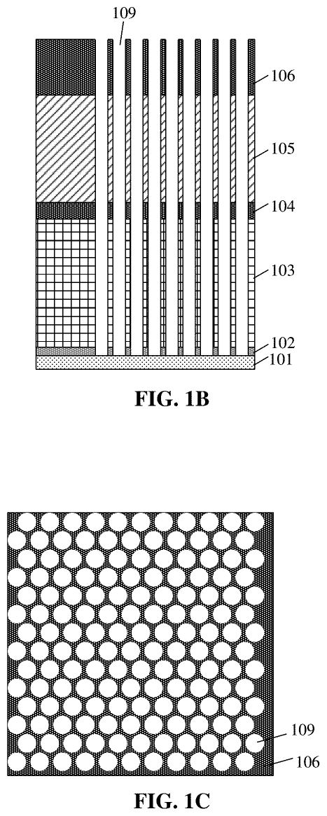

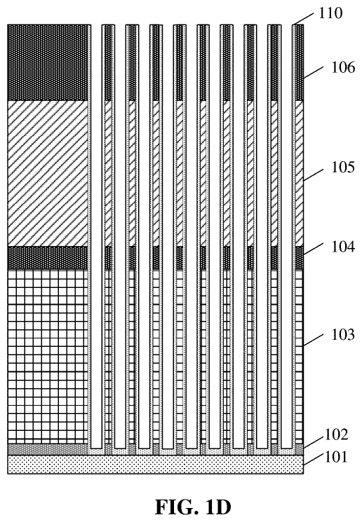

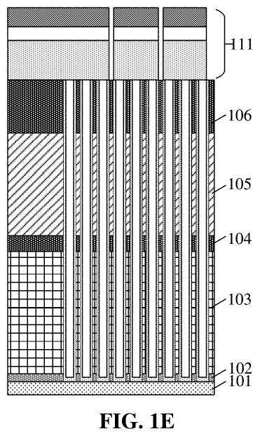

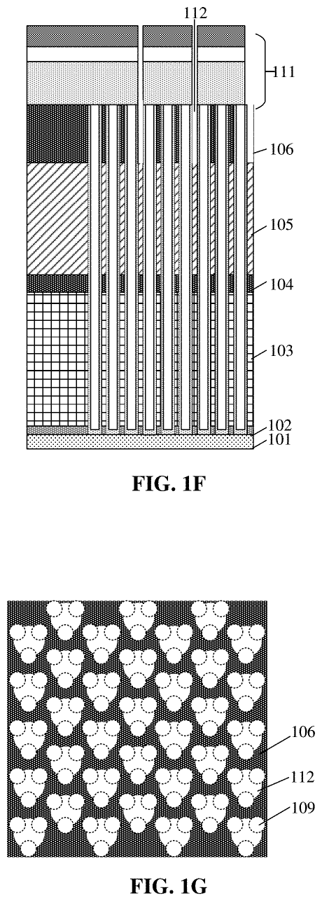

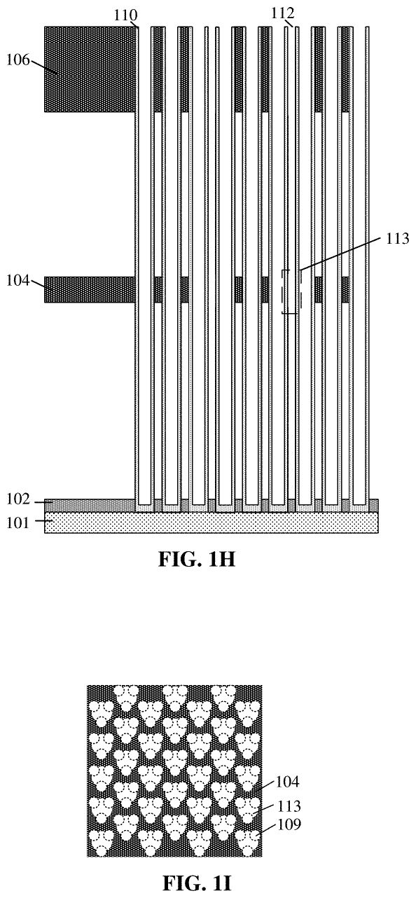

FIG. 1A to FIG. 1I are schematic diagrams of forming a capacitor in some implementations. As shown in FIG. 1A, an etching stop layer 102, a first sacrificial layer 103, a first support layer 104, a second sacrificial layer 105, and a second support layer 106 covering a substrate 101 are sequentially formed on the substrate 101. Then, a patterned first mask layer 107 and a patterned second mask layer 108 covering the second support layer 106 are sequentially formed. A structure covering the substrate 101 is etched on the basis of the first mask layer 107 and the second mask layer 108 until the etching stop layer 102 is exposed. The first mask layer 107 and the second mask layer 108 are removed to form capacitance holes 109, as shown in FIG. 1B.

FIG. 1C is a top view of an etched capacitor in some implementations. The arrangement of the capacitance holes 109 is as shown in FIG. 1C. After the capacitance holes 109 are formed, titanium nitride is deposited on an inner wall of each of the capacitance holes to form first electrode layers 110, as shown in FIG. 1D.

With reference to FIG. 1E to FIG. 1G, a patterned third mask layer 111 covering the etched second support layer 106 is formed, and the second support layer 106 is etched on the basis of the third mask layer, so as to form first openings 112 on the second support layer. FIG. 1G is a top view of a second support layer with first openings. The position relationship between the first openings 112 and the capacitance holes 109 is shown in FIG. 1G.

With reference to FIG. 1H and FIG. 1I, the second sacrificial layer 105 is removed through the first openings 112. Second openings 113 are formed on the first support layer 104 on the basis of the first openings, as shown in a dotted box in FIG. 1H. FIG. 1I is a cross-sectional view of the first support layer with the second openings. The position relationship between the second openings 113 and the capacitance holes 109 is shown in FIG. 1I.

In some implementations, since the positions of the second openings 112 on the first support layer and the positions of the first openings 113 on the second support layer in the direction parallel to the substrate are the same, that is, the projection positions of the second openings 112 in the direction perpendicular to the substrate and the projection positions of the first openings 113 in the direction perpendicular to the substrate are the same, the sidewall of a portion of the first electrode layers in the capacitor in some implementations does not have a support layer to support the first electrode layers, so that there is a risk of collapse of the electrode layers in the capacitor during manufacturing and using, resulting in the failure of the capacitor.

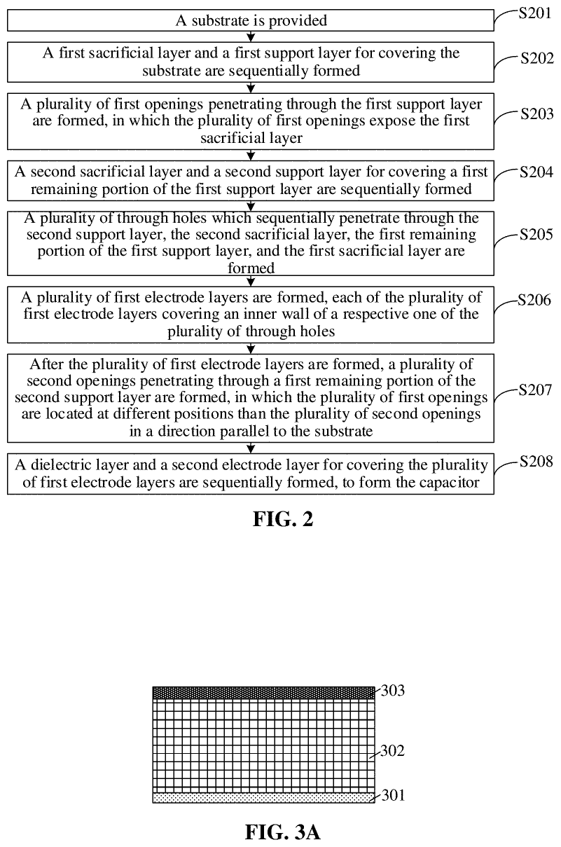

On the basis of the problem in some implementations, the embodiment of the disclosure provides a method for forming a capacitor. FIG. 2 is an optional flowchart of a method for forming a capacitor according to an embodiment of the disclosure. As shown in FIG. 2, the capacitor may be formed by the following operations.

In S201: a substrate is provided.

In S202: a first sacrificial layer and a first support layer for covering the substrate are sequentially formed.

In S203: a plurality of first openings penetrating through the first support layer are formed, in which the plurality of first openings expose the first sacrificial layer.

In S204: a second sacrificial layer and a second support layer for covering a first remaining portion of the first support layer are sequentially formed.

In S205: a plurality of through holes which sequentially penetrate through the second support layer, the second sacrificial layer, the first remaining portion of the first support layer, and the first sacrificial layer are formed.

In S206: a plurality of first electrode layers are formed, each of the plurality of first electrode layers covering an inner wall of a respective one of the plurality of through holes.

In S207: after the plurality of first electrode layers are formed, a plurality of second openings penetrating through a first remaining portion of the second support layer are formed, in which the plurality of first openings are located at different positions than the plurality of second openings in a direction parallel to the substrate.

In S208: a dielectric layer and a second electrode layer for covering the plurality of first electrode layers are sequentially formed, so as to form the capacitor.

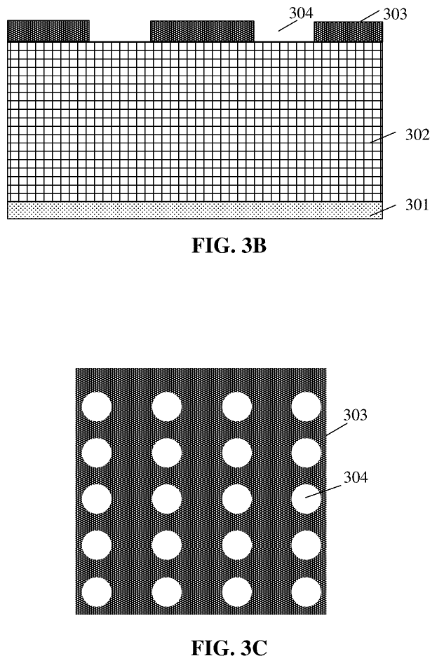

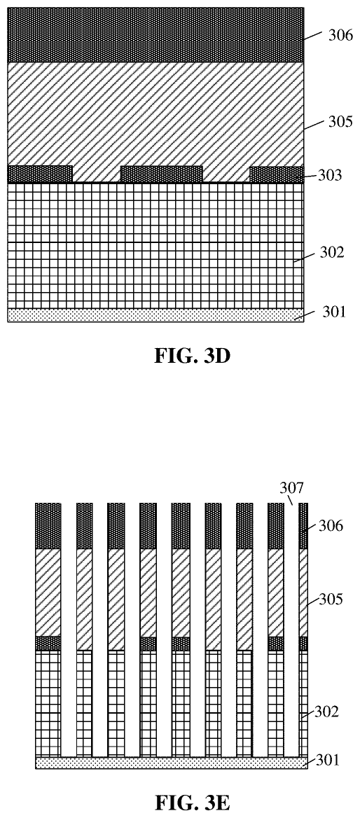

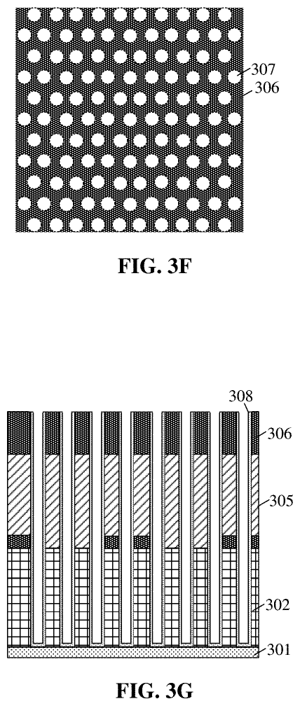

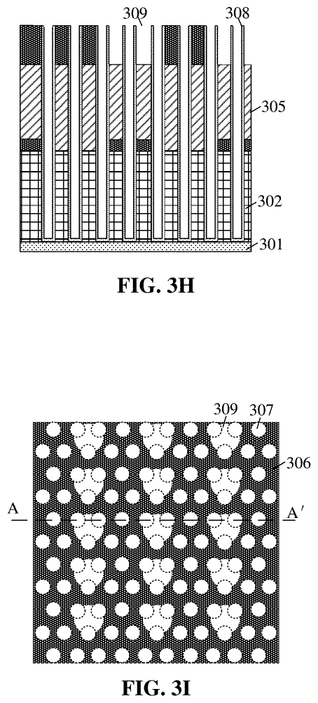

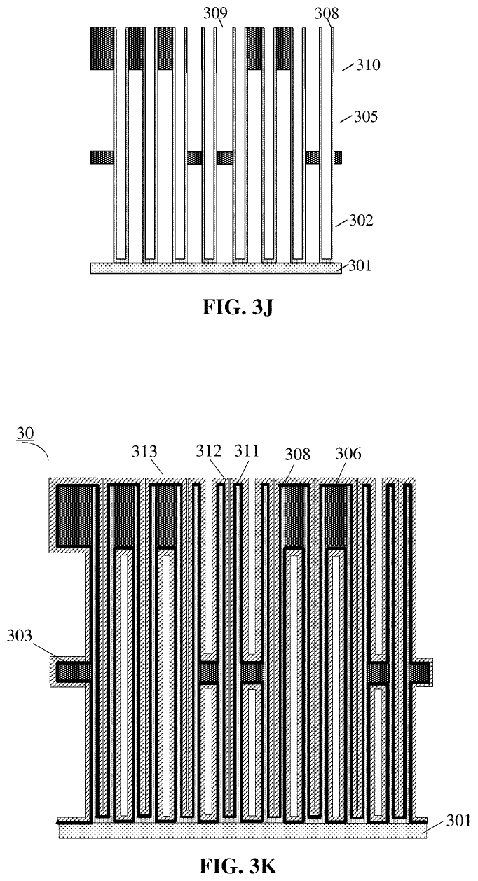

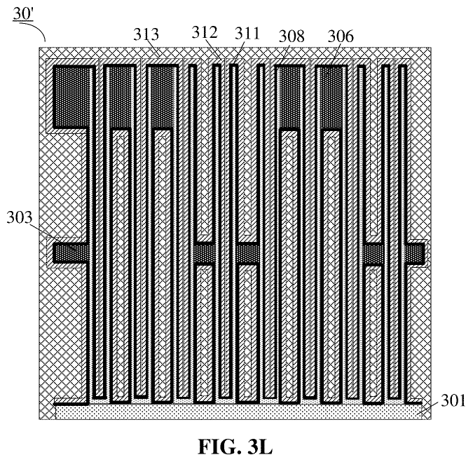

With reference to FIG. 3A to FIG. 3J, the method for forming the capacitor provided by the embodiments of the disclosure is further described in detail.

As shown in FIG. 3A, S201 and S202 are performed, in which a material of a substrate 301 in S201 may be silicon, silicon nitride, or gallium nitride.

In the embodiments of the disclosure, a first sacrificial layer 302 and a first support layer 303 for covering the substrate 301 may be sequentially formed through a Physical Vapor Deposition (PVD) process or a Chemical Vapor Deposition (CVD) process.

Herein, in order to facilitate subsequent etching of the bottom portion, the first sacrificial layer 302 may be made of a soft material, such as Phosphoro Silicate Glass (PSG), Boro-phospho-Silicate Glass (BPSG), or Fluoro Silicate Glass (FSG). The first support layer 303 may be a nitride, such as silicon nitride carbide or silicon nitride boride.

In some embodiments, after the first support layer 303 is formed, S203 is performed, in which a plurality of first openings 304 penetrating through the first support layer 303 are formed. The plurality of first openings 304 expose the first sacrificial layer 302, as shown in FIG. 3B. Herein, the first openings may be formed by forming a patterned first mask layer (not shown in the figures) covering the first support layer, and etching the first support layer on the basis of the first mask layer.

The first mask layer may be formed by sequentially stacking an Armorphous Carbon Layer (ACL), a Spin on Hardmask (SOH) and Tetraethyl Orthosilicate (TEOS) on one another.

In some embodiments, a specific method for forming the patterned first mask layer includes the following operations. Firstly, a first mask layer covering the first support layer is formed. Then, a patterned photoresist layer is formed on an upper surface of the first mask layer, and the first mask layer is etched on the basis of the patterned photoresist layer to transfer a pattern in the patterned photoresist layer into the first mask layer, so as to form the patterned first mask layer. Finally, the patterned photoresist layer is removed.

With reference to FIG. 3C, FIG. 3C is a top view of an etched first support layer according to an embodiment of the disclosure. The positions of the first openings 304 in the first support layer 303 are shown in FIG. 3C.

It should be noted that the embodiments of the disclosure only exemplarily provide a feasible shape of the first opening. The first opening in the embodiments of the disclosure may also be in a rectangular shape, a square shape, or some other feasible shapes in a top view, which is not limited thereto in the embodiments of the disclosure.

After the plurality of first openings are formed, S204 is performed, in which a second sacrificial layer 305 and a second support layer 306 for covering a first remaining portion of the first support layer are sequentially formed through a PVD or CVD process, as shown in FIG. 3D. The second sacrificial layer 305 may be a material such as PSG, BPSG, or FSG. The second support layer 306 may be a nitride, such as silicon nitride carbide or silicon nitride boride.

In some embodiments, when the second sacrificial layer 305 is formed on a surface of the first remaining portion of the first support layer, the first openings 304 in the first support layer 303 are filled with the second sacrificial layer 305.

Next, with reference to FIG. 3E and FIG. 3F, S205 is performed, in which a plurality of through holes 307 which sequentially penetrate through the second support layer 306, the second sacrificial layer 305, the first remaining portion of the first support layer 303 and first sacrificial layer 302 are formed. Herein, the through holes may be formed by forming a patterned photoresist layer (not shown in the figures) covering the second support layer, and etching the second support layer, the second sacrificial layer, the first remaining portion of the first support layer, and the first sacrificial layer on the basis of the photoresist layer.

FIG. 3F is a top view of the second support layer after the through holes are formed according to an embodiment of the disclosure. The positions of the through holes 307 in the second support layer are shown in FIG. 3F.

After the plurality of through holes 307 are formed, S206 is performed, in which a plurality of first electrode layers 308 are formed, each of the plurality of first electrode layers covering an inner wall of a respective one of the plurality of through holes, as shown in FIG. 3G. In some embodiments, the plurality of first electrode layers may be formed through an atomic layer deposition process. The material of the first electrode layer may be titanium nitride (TiN).

In some embodiments, after the plurality of first electrode layers are formed, S207 is performed, in which a plurality of second openings 309 penetrating through a first remaining portion of the second support layer are formed, as shown in FIG. 3H.

In some embodiments, the plurality of second openings may be formed by forming a patterned second mask layer (not shown in the figures) covering the first remaining portion of the second support layer, and etching the first remaining portion of the second support layer on the basis of the second mask layer. The patterned second mask layer and the abovementioned patterned first mask layer are formed by the same material and method, which will not be repeated in the embodiments of the disclosure.

FIG. 3I is a top view of the second support layer after the second openings are formed according to an embodiment of the disclosure. The positions of the second openings and the through holes in the second support layer are shown in FIG. 3I. FIG. 3H is a cross-sectional view taken along a dotted line AA′ in FIG. 3I.

In some embodiments, in the direction parallel to the substrate, the pattern positions of the patterned first mask layer are different from the pattern positions of the patterned second mask layer. Therefore, with reference to FIG. 3C and FIG. 3I, in the direction parallel to the substrate, the positions of the first openings 304 in the first support layer is different from the positions of the second openings 309 in the second support layer. That is, the projection positions of the first openings 304 in the direction perpendicular to the substrate are different from the projection positions of the second openings 309 in the direction perpendicular to the substrate.

That is to say, the first support layer 303 in which the first openings 304 are formed and the second support layer 306 in which the second openings 309 are formed are complementary to each other in the direction perpendicular to the substrate, so that there is at least one support layer between any two adjacent first electrode layers.

In some embodiments, the shapes of the first opening and the second opening may be the same or may be different.

In some embodiments, after the plurality of second openings are formed, the second sacrificial layer is removed through the plurality of second openings. Therefore, the method further includes the following operations.

A remaining portion of the second sacrificial layer is removed through the plurality of second openings, so as to expose the plurality of first openings.

After the remaining portion of the second sacrificial layer is removed, a remaining portion of the first sacrificial layer is removed through the plurality of exposed first openings to form a plurality of first voids.

In some embodiments, the second sacrificial layer 305 and the first sacrificial layer 302 may be sequentially removed by a wet etching solution through a wet etching process, so as to form the plurality of first voids 310, as shown in FIG. 3J. The wet etching solution may include a mixture of Diluted Hydrofluoric Acid (DHF) and ammonia (NH₄OH), or may include a mixture of the DHF and Tetramethylammonium Hydroxide (TMAH).

It should be noted that after the plurality of first openings 304 are formed in the foregoing embodiments, the second sacrificial layer 305 is formed on the first support layer 303 with the first openings 304. Therefore, the first openings 304 are filled with the second sacrificial layer 305. Since the material of the first support layer 303 is different from the material of the second sacrificial layer 305, the first support layer 303 with the openings will not be removed when the second sacrificial layer 305 is removed through a wet etching process. Therefore, after the second sacrificial layer 305 is removed, the first openings 304 will be exposed, that is, the first openings 304 are not filled.

After the plurality of first voids are formed, S208 is performed, in which a dielectric layer 311 and a second electrode layer 312 for covering the plurality of first electrode layers 308 are sequentially formed, so as to form the capacitor 30, as shown in FIG. 3K.

In some embodiments, S208 may include the following operations. The dielectric layer and the second electrode layer for covering the plurality of first electrode layers are sequentially formed in the plurality of through holes in a radial direction of each of the plurality of through holes. Simultaneously, the dielectric layer and the second electrode layer for covering the plurality of first electrode layers, a second remaining portion of the first support layer, and a second remaining portion of the second support layer are sequentially formed in the plurality of first voids.

After the second electrode layer is formed, the method further includes the following operation.

Gaps in the second electrode layer are filled with a conductive material, so as to form a conductive structure.

In some embodiments, the dielectric layer and the second electrode layer may be formed through an atomic layer deposition process. The dielectric layer may be made of silicon oxide or zirconium oxide. The material of the second electrode layer may be titanium nitride (TiN).

With reference to FIG. 3L, the dielectric layer 311 and the second electrode layer 312 for covering the plurality of first electrode layers 308 are formed, and the gaps in the second electrode layer 312 are filled with the conductive material 313, so as to form the conductive structure.

In some embodiments, the conductive material may be a material such as silicon germanium or lanthanum oxide.

In some embodiment, a capacitor 30′ is formed after the conductive structure is formed.

According to the method for forming the capacitor provided by the embodiments of the disclosure, when the first support layer and the second support layer are formed, in the direction parallel to the substrate, openings at different positions are formed in the first support layer and in the second support layer, so that there is at least one support layer between any two adjacent first electrode layers in the capacitor to support the first electrode layers, which improves the support stability of the first electrode layers, and reduces the risk of collapse of the first electrode layers during manufacturing and using. Thus, the top portions of the first electrode layers will not be interconnected to each other after collapse, thereby improving the performance of the capacitor.

In some embodiments, S206 may further include the following operation. Each of the plurality of first electrode layers filling the respective one of the plurality of through holes is formed. A width of each of the plurality of first electrode layers is the same as a width of each of the plurality of through holes in the direction parallel to the substrate.

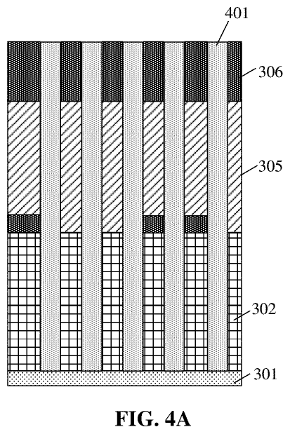

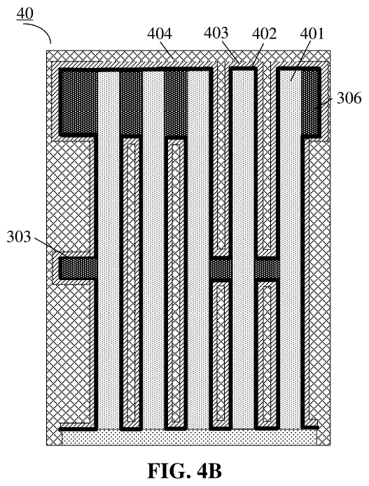

Based on the foregoing embodiments and FIG. 3F, FIG. 4A is a schematic diagram of forming a plurality of first electrode layers according to an embodiment of the disclosure. As shown in FIG. 4A, the width of the first electrode layer 401 is the same as the width of the through hole, that is, the first electrode layer 401 completely fills the whole through hole.

Herein, the first electrode layers may be formed through an atomic layer deposition process. The material of the first electrode layer may be titanium nitride (TiN).

In some embodiments, after the plurality of first electrode layers 401 are formed, a plurality of second openings penetrating through the first remaining portion of the second support layer are formed. Then, S208 is performed. S208 may further include the following operations.

The dielectric layer for covering the plurality of first electrode layers, a third remaining portion of the first support layer, and a third remaining portion of the second support layer are formed in the plurality of first voids.

The second electrode layer for covering the dielectric layer is formed.

After the second electrode layer is formed, the method further includes the following operation.

Gaps in the second electrode layer are filled with a conductive material, so as to form a conductive structure.

FIG. 4B is a schematic diagram of forming a conductive structure according to an embodiment of the disclosure. As shown in FIG. 4B, the dielectric layer 402 covers the first electrode layers 401, the third remaining portion of the second support layer 306, and the third remaining portion of the first support layer 303. The second electrode layer 403 covers the dielectric layer 402. Gaps in the second electrode layer 403 are filled with the conductive material 404, so as to form the conductive structure, thereby forming the capacitor 40.

The method for forming the capacitor provided by the embodiment of the disclosure may be applied to a single-layer capacitor 40, or may also be applied to a double-layer capacitor 30. With the method for forming the capacitor provided by the embodiment of the disclosure, there is at least one support layer between any two adjacent first electrode layers in the single-layer capacitor or the double-layer capacitor to support the first electrode layers, which improves the support stability of the capacitor.

In some embodiments, a plurality of contacts are formed in the substrate. Before the first sacrificial layer is formed, the method further includes the following operation.

An etching stop layer for covering the substrate provided with the plurality of contacts is formed.

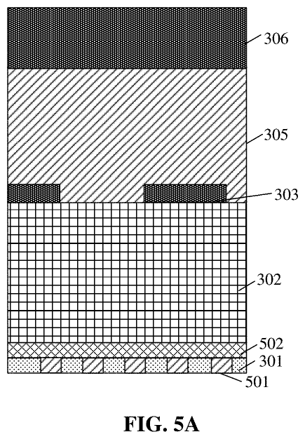

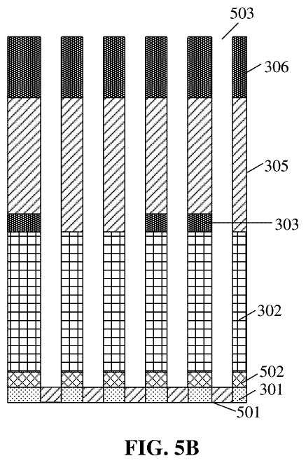

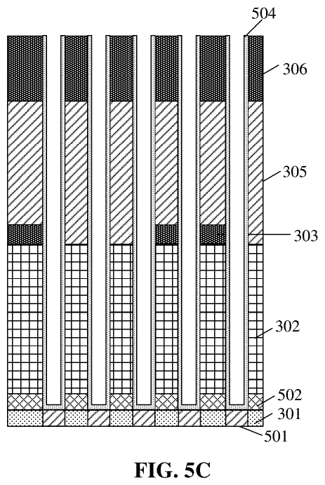

Based on the foregoing embodiments, with reference to FIG. 5A to FIG. 5C, the etching stop layer 502 for covering the substrate 301 provided with the plurality of contacts 501 is formed. The first sacrificial layer 302, the first support layer 303, the second sacrificial layer 305, and the second support layer 306 are sequentially formed on the etching stop layer 502. The forming operations are the same as S202 to S204 in the foregoing embodiments, which will not be repeated in the embodiment of the disclosure.

In some embodiments, S205 may further include the following operation.

The plurality of through holes 503 which sequentially penetrate through the second support layer 306, the second sacrificial layer 305, the first remaining portion of the first support layer 303, the first sacrificial layer 302, and the etching stop layer 502 are formed. Each of the plurality of through holes 503 exposes a respective one of the plurality of contacts 501.

In some embodiments, after the plurality of through holes are formed, a first electrode layer 504 is formed in each of the plurality of through holes, and each first electrode layer 504 is connected to a respective one of the plurality of contacts 501, as shown in FIG. 5C. After the plurality of first electrode layers are formed, a dielectric layer and a second electrode layer are sequentially formed, and gaps in the second electrode layer are filled with a conductive material, so as to form a conductive structure. The forming method is the same as that in the abovementioned embodiments.

In the embodiment of the disclosure, the substrate is provided with contacts. The first electrode layer is connected to the contact. The contacts are configured to connect the capacitor to a source or a drain of a transistor in the substrate.

In some embodiments, before the first sacrificial layer is formed, the method further includes the following operation.

An etching stop layer for covering the substrate is formed.

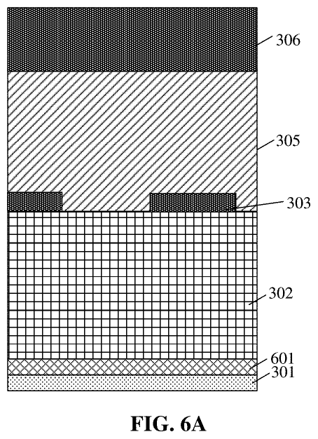

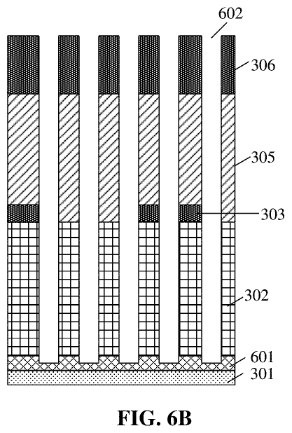

Based on the foregoing embodiments, with reference to FIG. 6A and FIG. 6B, the etching stop layer 601 for covering the substrate 301 is formed. The first sacrificial layer 302, the first support layer 303, the second sacrificial layer 305, and the second support layer 306 are sequentially formed on the etching stop layer 601. The forming operations are the same as S202 to S204 in the foregoing embodiments, which will not be repeated in the embodiment of the disclosure.

In some embodiments, S205 may further include the following operation. The plurality of through holes which sequentially penetrate through the second support layer, the second sacrificial layer, the first remaining portion of the first support layer, the first sacrificial layer, and a portion of the etching stop layer are formed. A bottom portion of each of the plurality of through holes is arranged in the etching stop layer.

With reference to FIG. 6B, the bottom portion of each of the plurality of through hole 602 is arranged in the etching stop layer 601. After the plurality of through holes are formed, a first electrode layer is formed on the inner wall of each through hole, and a dielectric layer and a second electrode layer are sequentially formed. The forming method is the same as that in the abovementioned embodiments.

In some embodiments, in the method for forming the capacitor provided in the disclosure, the thickness of the formed second support layer is greater than the thickness of the first support layer. In this way, the support stability of the top portions of the first electrode layers is improved, so that the top portions of the first electrode layers will not collapse to bridge, resulting in a short circuit of the capacitor.

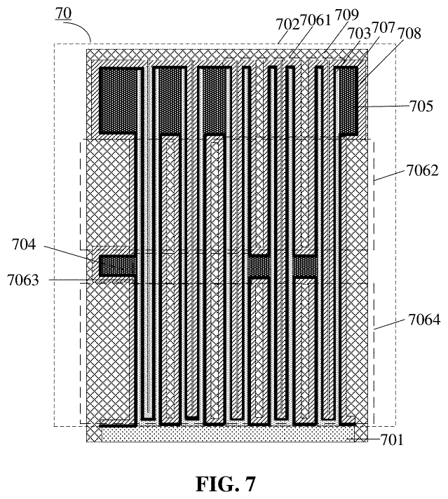

FIG. 7 is a partially schematic diagram of a semiconductor device according to an embodiment of the disclosure. As shown in FIG. 7, the semiconductor device 70 at least includes: a substrate 701, and a capacitor 702.

The capacitor 702 includes: a plurality of first electrode layers 703 arranged perpendicular to the substrate 701; a first support layer 704 arranged parallel to the substrate 701, the first support layer 704 being connected to a portion of each of sidewalls of the plurality of first electrode layers 703; a second support layer 705 arranged parallel to the first support layer 704, the second support layer 705 being connected to a portion of each of the sidewalls of the plurality of first electrode layers 703, and the first support layer 704 being arranged between the second support layer 705 and the substrate 701; and a conductive structure 706, the conductive structure including a first portion, a second portion, a third portion, and a fourth portion, which are sequentially connected to one another, the first portion penetrating through the second support layer, the second portion being arranged between the second support layer and the first support layer, the third portion penetrating through the first support layer, and the fourth portion being arranged between the first support layer and the substrate.

In a direction perpendicular to a plane where the substrate 701 is located, a projection of the first portion 7061 does not overlap a projection of the third portion 7063.

In some embodiments, the capacitor 70 further includes: a dielectric layer 707, the dielectric layer 707 covering surfaces of the plurality of first electrode layers 703, a surface of the first support layer 704, and a surface of the second support layer 705; a second electrode layer 708, the second electrode layer 708 covering a surface of the dielectric layer 707; and a conductive material 709, gaps in the second electrode layer 708 are filled with the conductive material 709.

It should be noted that the conductive structure 706 is composed of the first electrode layers 703, the dielectric layer 707, the second electrode layer 708, and the conductive material 709.

In some embodiments, the conductive structure 706 includes the first portion 7061 penetrating through the second support layer, as shown in the dotted box in FIG. 7. Herein, the position of the first portion 7061 in the second support layer is consistent with the position of the second opening and through hole in the second support layer in the foregoing embodiment.

The second portion 7062 is arranged between the second support layer 705 and the first support layer 704. As shown in the dotted box in FIG. 7, the position of the second portion 7062 in the capacitor is consistent with the position of the second sacrificial layer in the foregoing embodiments.

The third portion 7063 penetrates through the first support layer 704, as shown in the dotted box in FIG. 7. The position of the third portion 7063 in the first support layer is consistent with the position of the first opening and the through hole in the first support layer in the foregoing embodiments.

The fourth portion 7064 is arranged between the first support layer 704 and the substrate 701. As shown in the dotted box in FIG. 7, the position of the fourth portion 7064 in the capacitor is consistent with the position of the first sacrificial layer in the foregoing embodiments.

It should be noted that the first portion 7061, the second portion 7062, the third portion 7063, and the fourth portion 7064 are sequentially connected to one another in the capacitor.

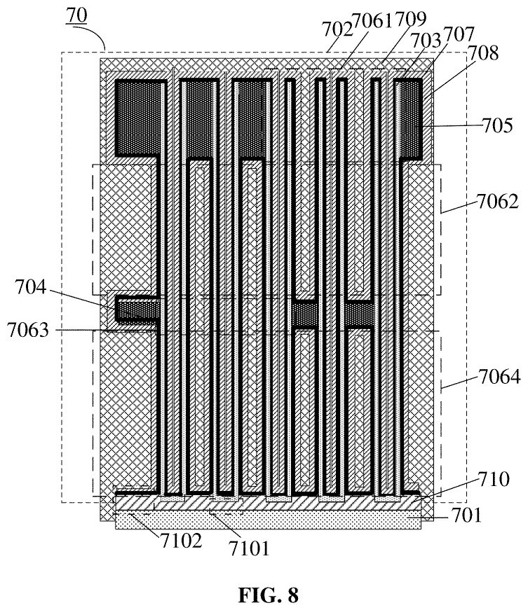

With reference to FIG. 8, in some embodiments, the semiconductor device 70 further includes an etching stop layer 710.

The etching stop layer 710 includes a first sublayer 7101 and a second sublayer 7102. The first sublayer 7101 is arranged between the substrate 701 and the plurality of first electrode layers 703. The second sublayer 7102 is arranged between the fourth portion 7064 and the substrate 701.

In some embodiments, a thickness of the first sublayer 7101 is less than a thickness of the second sublayer 7102.

In some embodiments, a material of the first support layer and a material of the second support layer include at least one of: silicon oxide, silicon nitride, silicon nitride carbide, or silicon oxynitride.

In some embodiments, a material of each of the plurality of first electrode layers includes a metal nitride and/or a metal silicide. A material of the second electrode layer includes a metal nitride and/or a metal silicide. A material of the dielectric layer includes at least one of: zirconium oxide, hafnium oxide, titanium zirconium oxide, ruthenium oxide, antimony oxide, or aluminum oxide.

In some embodiments, the first support layer and/or the second support layer are/is provided between any two adjacent first electrode layers, so that there is at least one support layer provided on the sidewall of each first electrode layer in the capacitor provided by the embodiment of the disclosure, which improves the support stability of the first electrode layers, and reduces the risk of collapse of the first electrode layers during manufacturing and using. Thus, the top portions of the first electrode layers will not be bridged, thereby improving the performance of the capacitor.

In the several embodiments provided in the disclosure, it should be understood that the disclosed device and method may be implemented in a non-target manner. The above described device embodiments are merely exemplary. For example, the unit division is merely logical function division, and may be other division in an actual implementation. For example, a plurality of units or components may be combined or integrated into another system, or some features may be ignored or not performed. In addition, the displayed or discussed components are coupled or directly coupled to each other.

The units described above as separate components may or may not be physically separated. Components presented as units may or may not be physical units, that is, may be located in one place or may be distributed over multiple network units. Part or all of these units may be selected according to practical requirements to achieve the objectives of the solutions of the embodiments.

The above descriptions are merely specific implementations of the disclosure, and are not intended to limit the protection scope of the disclosure. It is easy for those skilled in the art to convince modifications or substitutions within the technical scope disclosed in the disclosure. Therefore, the protection scope of the disclosure is subject to the protection scope of the claims.

What is claimed is:

1. A method for forming a capacitor, comprising:
providing a substrate;
sequentially forming a first sacrificial layer and a first support layer for covering the substrate;
forming a plurality of first openings penetrating through the first support layer, wherein the plurality of first openings expose the first sacrificial layer;
sequentially forming a second sacrificial layer and a second support layer for covering a first remaining portion of the first support layer;
forming a plurality of through holes which sequentially penetrate through the second support layer, the second sacrificial layer, the first remaining portion of the first support layer, and the first sacrificial layer;
forming a plurality of first electrode layers, each of the plurality of first electrode layers covering an inner wall of a respective one of the plurality of through holes;
after forming the plurality of first electrode layers, forming a plurality of second openings penetrating through a first remaining portion of the second support layer, wherein the plurality of first openings are located at different positions than the plurality of second openings in a direction parallel to the substrate; and
sequentially forming a dielectric layer and a second electrode layer for covering the plurality of first electrode layers, to form the capacitor.

2. The method for forming the capacitor according to claim 1, wherein before forming the dielectric layer and the second electrode layer, the method further comprises:
removing a remaining portion of the second sacrificial layer through the plurality of second openings, to expose the plurality of first openings; and
after removing the remaining portion of the second sacrificial layer, removing a remaining portion of the first sacrificial layer through the plurality of first openings to form a plurality of first voids.

3. The method for forming the capacitor according to claim 2, wherein sequentially forming the dielectric layer and the second electrode layer for covering the plurality of first electrode layers comprises:
sequentially forming, in the plurality of through holes, in a radial direction of each of the plurality of through holes, the dielectric layer and the second electrode layer for covering the plurality of first electrode layers, and simultaneously, sequentially forming, in the plurality of first voids, the dielectric layer and the second electrode layer for covering the plurality of first electrode layers, a second remaining portion of the first support layer, and a second remaining portion of the second support layer;
wherein after forming the second electrode layer, the method further comprises:
filling gaps in the second electrode layer with a conductive material to form a conductive structure.

4. The method for forming the capacitor according to claim 2, wherein forming the plurality of first electrode layers, each of the plurality of first electrode layers covering the inner wall of the respective one of the plurality of through holes comprises:
forming each of the plurality of first electrode layers filling the respective one of the plurality of through holes, wherein a width of each of the plurality of first electrode layers is the same as a width of each of the plurality of through holes in the direction parallel to the substrate.

5. The method for forming the capacitor according to claim 4, wherein sequentially forming the dielectric layer and the second electrode layer for covering the plurality of first electrode layers comprises:
forming, in the plurality of first voids, the dielectric layer for covering the plurality of first electrode layers, a third remaining portion of the first support layer, and a third remaining portion of the second support layer;
forming the second electrode layer for covering the dielectric layer;
wherein after forming the second electrode layer, the method further comprises:
filling gaps in the second electrode layer with a conductive material to form a conductive structure.

6. The method for forming the capacitor according to claim 1, wherein a plurality of contacts are formed in the substrate, and wherein before forming the first sacrificial layer, the method further comprises:
forming an etching stop layer for covering the substrate provided with the plurality of contacts;
wherein forming the plurality of through holes which sequentially penetrate through the second support layer, the second sacrificial layer, the first remaining portion of the first support layer, and the first sacrificial layer comprises:
forming the plurality of through holes which sequentially penetrate through the second support layer, the second sacrificial layer, the first remaining portion of the first support layer, the first sacrificial layer, and the etching stop layer, wherein each of the plurality of through holes exposes a respective one of the plurality of contacts.

7. The method for forming the capacitor according to claim 6, wherein after the plurality of first electrode layers are formed, each of the plurality of first electrode layers is connected to the respective one of the plurality of contacts.

8. The method for forming the capacitor according to claim 1, wherein before forming the first sacrificial layer, the method further comprises:
forming an etching stop layer for covering the substrate;
wherein forming the plurality of through holes which sequentially penetrate through the second support layer, the second sacrificial layer, the first remaining portion of the first support layer, and the first sacrificial layer comprises:
forming the plurality of through holes which sequentially penetrate through the second support layer, the second sacrificial layer, the first remaining portion of the first support layer, the first sacrificial layer, and a portion of the etching stop layer, wherein a bottom portion of each of the plurality of through holes is arranged in the etching stop layer.

9. The method for forming the capacitor according to claim 1, wherein a thickness of the second support layer is greater than a thickness of the first support layer.

10. A semiconductor device, comprising at least:
a substrate; and
a capacitor, the capacitor comprising:
a plurality of first electrode layers arranged perpendicular to the substrate;
a first support layer arranged parallel to the substrate, wherein the first support layer is connected to a first portion of each of sidewalls of the plurality of first electrode layers;
a second support layer arranged parallel to the first support layer, wherein the second support layer is connected to a second portion of each of the sidewalls of the plurality of first electrode layers, and the first support layer is arranged between the second support layer and the substrate; and
a conductive structure, the conductive structure comprising a first portion, a second portion, a third portion, and a fourth portion, which are sequentially connected to one another in a direction perpendicular to a plane where the substrate is located, wherein the first portion penetrates through the second support layer, the second portion is arranged between the second support layer and the first support layer, the third portion penetrates through the first support layer, and the fourth portion is arranged between the first support layer and the substrate,
wherein in the direction perpendicular to the plane where the substrate is located, a projection of the first portion does not overlap a projection of the third portion.

11. The semiconductor device according to claim 10, wherein the capacitor further comprises:
a dielectric layer, wherein the dielectric layer covers surfaces of the plurality of first electrode layers, a surface of the first support layer, and a surface of the second support layer;
a second electrode layer, wherein the second electrode layer covers a surface of the dielectric layer; and
a conductive material, wherein gaps in the second electrode layer are filled with the conductive material.

12. The semiconductor device according to claim 10, further comprising:
an etching stop layer, the etching stop layer comprising a first sublayer and a second sublayer,
wherein the first sublayer is arranged between the substrate and the plurality of first electrode layers,
wherein the second sublayer is arranged between the fourth portion and the substrate, and
wherein a thickness of the first sublayer is less than a thickness of the second sublayer.

13. The semiconductor device according to claim 10, wherein a material of the first support layer and a material of the second support layer comprise at least one of:
silicon oxide,
silicon nitride,
silicon nitride carbide, or
silicon oxynitride.

14. The semiconductor device according to claim 11, wherein
a material of each of the plurality of first electrode layers comprises at least one of a metal nitride or a metal silicide;
a material of the second electrode layer comprises at least one of a metal nitride or a metal silicide; and
a material of the dielectric layer comprises at least one of: zirconium oxide, hafnium oxide, titanium zirconium oxide, ruthenium oxide, antimony oxide, or aluminum oxide.

15. The semiconductor device according to claim 10, wherein at least one of the first support layer or the second support layer is provided between any two adjacent first electrode layers of the plurality of first electrode layers.
